(19) United States
(12) Patent Application Publication
(10) Pub. No.: US 2004/0179340 A1
(43) Pub. Date: Sep. 16, 2004

(54) Heat sink fastener

(76) Inventor: Fang-Cheng Lin, Chungho City (TW)

Correspondence Address: Jackson Walker L.L.P., Suite 2100, 112 E. Pecan Street, San Antonio, TX, 78205, US

(21) Appl. No.: 10/754,304

(22) Filed: Jan. 9, 2004

(30) Foreign Application Priority Data
Mar. 10, 2003 (TW) 092203561

(51) Int. Cl. H05K 7/20

(52) U.S. Cl. 361/704

(57) ABSTRACT

A heat sink fastener has a socket, resilient locking rail, a connector and a lever. The socket is mounted on a motherboard, and a CPU is mounted in the socket. The resilient locking rail has two ends with one end connected to the socket and the other end connected to the connector. The connector is mounted on the socket, and the lever is pivotally attached to the connector. When a heat sink is attached on the CPU, the lever is pressed and tightens the resilient locking rail, which presses the heat sink against the CPU. The heat sink is securely attached to the CPU by the heat sink fastener. The heat sink fastener is operated conveniently and accommodates an AMD Athlon K8 CPU.

### BACKGROUND OF THE INVENTION

1. Field of the Invention

The present invention relates to a heat sink fastener, and more particularly to a heat sink fastener that securely and easily attaches a heat sink to an AMD Athlon K8 CPU.

2. Description of Related Art

A CPU is the heart of a computer and is absolutely essential for operation of the computer. However, a modern, high-speed CPU generates a quantity of heat that will damage the CPU unless the heat is effectively dissipated. Thus how to dissipate the heat generated by the CPU quickly and effectively to prevent the CPU from being damaged by the heat is of major importance in this field. Therefore, a heat sink is mounted on the CPU.

Conventional heat sinks are made of metal with good heat conductivity and are mounted on the surface of the CPU so the heat generated by CPU is conducted to the heat sink. To keep heat sinks from separating from CPUs, heat sink fasteners are used to attach the heat sinks to the CPUs.

Numerous types of CPUs are manufactured, and each type has a unique configuration. Consequently, different heat sinks are manufactured to match respectively the various CPU types. Unique heat sink fasteners have been developed to accommodate respectively the different CPUs and heat sinks.

Advanced Micro Devices (AMD) company has invented a new type CPU, the Athlon K8 CPU. None of the existing heat sink fasteners can be used to effectively attach a heat sink to the Athlon K8 CPU. The present invention is provided to overcome the foregoing deficiency.

### SUMMARY OF THE INVENTION

The main objective of the present invention is to provide a heat sink fastener that securely and conveniently attaches a heat sink to an Advanced Micro Devices (AMD) Athlon K8 CPU.

To achieve the objective, a heat sink fastener in accordance with the present invention comprises a socket, a resilient locking rail, a connector and a lever. The socket is mounted on a motherboard, and an AMD CPU is mounted in the socket. The resilient locking rail has two ends with one end connected to the socket and the other end connected to the connector. The connector is mounted on the socket, and the lever is pivotally mounted on the connector. When a heat sink is attached to the CPU, the lever is pressed and tightens the resilient locking rail, which presses the heat sink against the CPU. The heat sink is securely attached to the CPU by the heat sink fastener. The heat sink fastener is operated conveniently and accommodates an AMD Athlon K8 CPU.

Further benefits and advantages of the present invention will become apparent after a careful reading of the detailed description with appropriate reference to the accompanying drawings.

### BRIEF DESCRIPTION OF THE DRAWINGS

FIG. 1 is an exploded perspective view of a heat sink fastener in accordance with the present invention;

FIG. 2 is a perspective view of the heat sink fastener in FIG. 1; and.

FIG. 3 is an operational perspective view of the heat sink fastener in FIG. 1 attaching a heat sink.

### DETAILED DESCRIPTION OF THE INVENTION

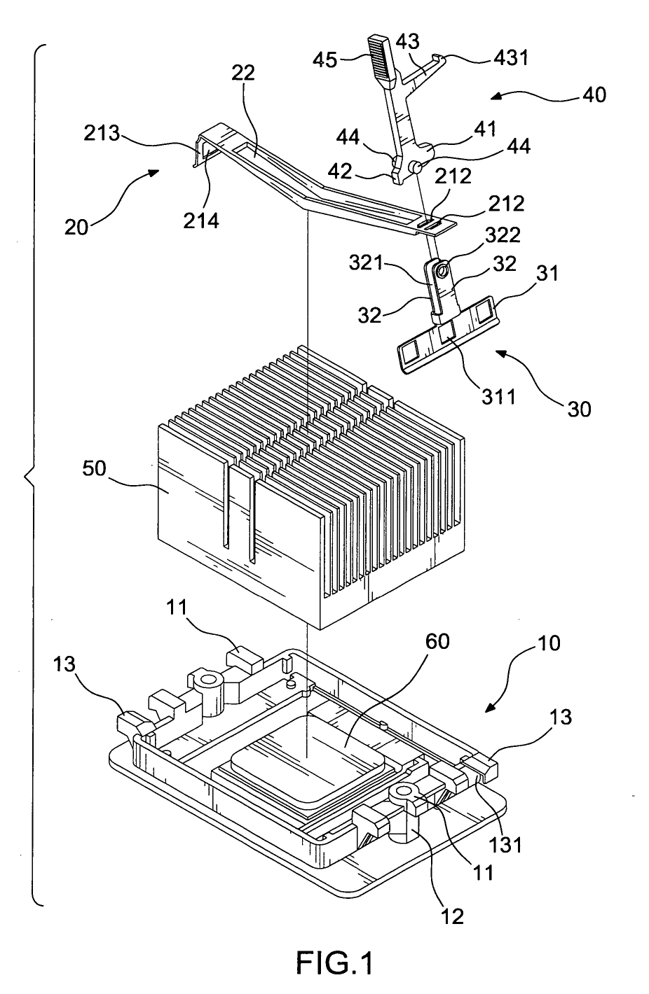

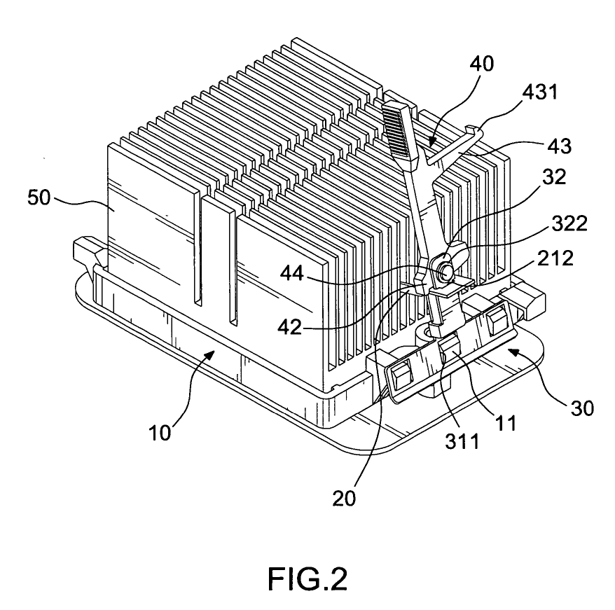

With reference to FIGS. 1 and 2, a heat sink fastener in accordance with the present invention comprises a socket (10), a resilient locking rail (20), a connector (30) and a lever (40). The socket (10) is rectangular and has two ends (not numbered), a middle (not numbered), a through hole (not numbered), four corners (not numbered), multiple tabs (11), multiple stubs (12) and multiple catches (13). Each end has a middle (not numbered). The through hole is formed in the middle of the socket (10) in which a CPU (60) is mounted. The multiple tabs (11) are formed integrally with, evenly spaced on and extend upward and outward from the two ends of the socket (10). The multiple stubs (12) are formed respectively integrally with and extend downward from the two ends. When the socket (10) has two stubs (12), one stub (12) is formed at the middle of each end. The stubs (12) are used to mount the socket (10) on a motherboard (not shown). The multiple catches (13) are formed at diametrically opposite corners and extend outward respectively from the two ends, and each catch (13) has a notch (131).

The resilient locking rail (20) is V-shaped and has a socket end (not numbered), a middle (not numbered), a connector end (not numbered), two transverse slots (212), a channel (22) and a lip (213). The connector end has two side edges (not numbered). The two transverse slots (212) are parallel and are formed in the connector end. The channel (22) is formed in the middle and parallel with the resilient locking rail (20). The lip (213) is formed integrally with and extends downward from the socket end of the resilient locking rail (20) and has a tab hole (214) in the lip (213).

The connector (30) is T-shaped and has a base (31), two legs (32) and a gap (321). The base (31) has multiple eyes (311) corresponding respectively to the tabs (11) on one end of the socket (10). Each leg (32) has a proximal end (not numbered), a distal end (not numbered) and a pivot hole (322). The legs (32) are parallel and extend perpendicular from the base (31). The pivot hole (322) is formed in the distal end of the leg (32). The gap (321) is formed between the two legs (32).

The lever (40) has a proximal end (not numbered), a distal end (not numbered), an eccentric knob (41), a positive limit (42), a latch (43), two pivot stubs (44) and a thumb tab (45). The proximal end has two edges (not numbered) and two faces (not numbered). The distal end has two edges (not numbered). The eccentric knob (41) is formed integrally with and protrudes outward from one side of the proximal end, and the positive limit (42) is formed integrally with and protrudes outward and downward from the other side of the proximal end. The two pivot stubs (44) protrude perpendicular respectively from faces of the proximal end and are axially aligned with each other. The latch (43) is formed integrally with and extends perpendicular from the edge of the distal end corresponding to the eccentric knob (41) and has a proximal end (not numbered), a distal end (not numbered) and a barb (431). The barb (431) is formed on the distal end. The thumb tab (45) is formed on and extends out from the other edge on the distal end of the lever (40).

The socket (10) is mounted on the motherboard by the stubs (12), the CPU (60) is mounted in the through hole in the socket (10), and a heat sink (50) is mounted on the CPU (60). The tab hole (214) in the lip (213) of the resilient locking rail (20) engages a tab (11) on one end of the socket (10), and multiple fins (not numbered) of the heat sink (50) are passed through the channel (22) in the resilient locking rail (20). The legs (32) of the connector (30) are passed upward through the corresponding transverse slots (212) in the resilient locking rail (20), and the eyes (311) in the base (31) of the connector (30) engage the corresponding tabs (11) on the other end of the socket (10). The proximal end of the lever (40) is mounted pivotally in the gap (321) between the legs (32) of the connector (30), and the pivot stubs (44) pivotally engage respectively the pivot holes (322) in the legs (32). The positive limit (42) of the lever (40) abuts one side edge of the connector end of the resilient locking rail (20).

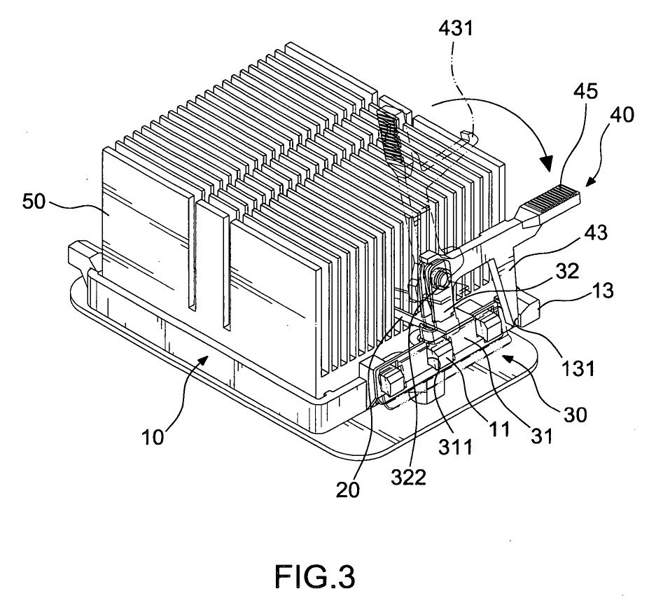

With further reference to FIG. 3, the heat sink (50) is mounted on the CPU (60) by pivoting the thumb tab (45) of the lever (40) so the eccentric knob (41) on the lever (40) presses the connector end of the resilient locking rail (20) down. The barb (431) on the latch (43) of the lever (40) engages the notch (131) in the catch (13) on the socket (10) to securely hold the heat sink (50) on the CPU (60).

When the heat sink (50) needs to be removed, the barb (431) on the latch (43) of the lever (40) is disengaged from the notch (131) in the catch (13) on the socket (10), and the lever (40) is pivoted away from the catch (13) so the eccentric knob (41) releases the connector end of the locking rail (20). The lever (40) is disconnected and removed from the connector (30), and the locking rail (20) is removed from the heat sink (50). Then the heat sink (50) can be easily removed from the CPU (60). The heat sink fastener in accordance with the present invention is operated conveniently and securely attaches the heat sink (50) to the CPU (60) so the heat generated by CPU is conducted to the heat sink (50).

Although the invention has been explained in relation to its preferred embodiment, many other possible modifications and variations can be made without departing from the spirit and scope of the invention as hereinafter claimed.

What is claimed is:

1. A heat sink fastener comprising:
a socket having
four corners
two ends respectively having a middle;
a middle;
a through hole formed in the middle of the socket;
multiple tabs respectively and symmetrically formed integrally with and extending upward and outward from the two ends of the socket; and
multiple catches formed on diametrically opposite corners and extending outward respectively from the two ends;
a V-shaped resilient locking rail connected to the socket to hold a heat sink on a CPU and having a socket end;
a middle;
a connector end having two side edges;
two parallel transverse slots formed in the connector end; and
a lip formed integrally with and extending downward from the socket end of the resilient locking rail and mounted on one of the multiple tabs on one end of the socket;
a connector mounted between the socket and the locking rail and having
a base having multiple eyes that correspond respectively to the tabs on one end of the socket;
two parallel legs respectively extending perpendicular from the base and passing respectively through the transverse slots in the connector end of the resilient locking rail; and
a gap formed between the two legs; and
a lever pivotally mounted in the gap between the two legs of the connector and having
a proximal end having two edges and two faces;
a distal end having two edges;
an eccentric knob formed integrally with and protruding outward from one edge of the proximal end; and
a latch formed integrally with and extending perpendicular from the edge of the distal end corresponding to the edge of the proximal end with the eccentric knob to engage one of the catches of the socket.

2. The heat sink fastener as claimed in claim 1, wherein the resilient locking rail has a channel formed in the middle and parallel with the resilient locking rail and has a tab hole in the lip on the socket end of the resilient locking rail.

3. The heat sink fastener as claimed in claim 1, wherein the each leg of the connector respectively has a proximal end;
a distal end; and
a pivot hole formed in the distal end of the leg; and
the lever has two pivot stubs protruding perpendicular respectively from the faces of the proximal end of the lever and engaging respectively with the pivot holes in the legs of the connector.

4. The heat sink fastener as claimed in claim 1, wherein the latch of the lever has a proximal end, a distal end and a barb formed on the proximal end.

5. The heat sink fastener as claimed in claim 1, wherein the lever has a positive limit formed integrally with and protruding outward and downward from the side of the proximal end opposite from the eccentric knob and a thumb tab formed on and extending out from the side on the distal end opposite to the latch.

6. The heat sink fastener as claimed in claim 1, wherein the socket has multiple stubs formed integrally with and extending downward from the two ends of the socket to mount the socket on a motherboard.

7. The heat sink fastener as claimed in claim 6, wherein the socket has two stubs formed respectively at the middle of the two ends of the socket.

8. The heat sink fastener as claimed in claim 1, wherein the multiple catches on the socket respectively have a notch in the catches.
